(19) United States
(12) Patent Application Publication
(10) Pub. No.: US 2002/0019714 A1
(43) Pub. Date: Feb. 14, 2002

(54) Optical position sensor and position determination method

(75) Inventors: Jeffrey Carliale, Salsbury, MA (US); Alvaro Kaplan, Newton, MA (US); John M. Kirkman JR., Kingston, NH (US)

Correspondence Address: Pilsbury Winthrop LLp, Intellectual Property Group, 1500 Tysons Boulevard, McLean, VA, 22102, US

(73) Assignee: Fluidsense Corporation, Newburyport, MA

(21) Appl. No.: 09/899,294

(22) Filed: Jul. 6, 2001

Related U.S. Application Data
(60) Provisional application No. 60/217,885, filed on Jul. 7, 2000.

(51) Int. Cl. G01R 13/00

(52) U.S. Cl. 702/73

(57) ABSTRACT

A method of position measurement by processing at least two phase displaced signals and by selecting one signal for position measurement at a given position point. Specifically, the two phase displaced signals are quadrature signals and the selected signal has a more linear waveform slope relative to time at a given position point than the non-selected signal.

This application is based on and claims priority from U.S. Provisional Patent Application No. 60/217,885, filed Jul. 7, 2000.

### FIELD OF THE INVENTION

The present invention relates to a system and method for high-resolution position measurement. Specifically the present invention is directed to a unique optical position sensor using moire fringe technique in combination with digital and analog signal processing to measure position, displacement, and proximity.

### BACKGROUND OF THE INVENTION

Position-measuring systems are designed to measure linear and angular displacements of external objects such as movable components of X-ray diffractometers, optical spectrometers, and micropositioners. Usually a position-measuring system contains an encoder which translates motion signals such as position, velocity, and acceleration into electrical signals. An encoder can be an absolute encoder or an incremental encoder. An absolute encoder has a unique value for each mechanical position, thus the position is known “absolutely”. An incremental encoder has output signals that repeat over the range of motion, and thus each mechanical position is not uniquely defined; the current position sensed is only incremental from the last position sensed.

Typically an encoder includes a position-measuring component such as a rotating shaft connected to the external object. The shaft is rotated as the object is adjusted. The encoder, in response, generates one or more electrical signals correlated to the degree of rotation. These signals are then processed by an external processing element to determine the position of the measurement device.

Some encoders, such as the Cannon K1 encoder, include an optical element for generating the analog electrical signals. For example, Cannon's encoder includes a diode laser and a miniaturized optical system connected to the rotating shaft. The optical system modulates the intensity of the diode laser's optical output as the shaft is rotated. The modulation results in a series of sinusoidal oscillations or “pulses” in the optical output. The number of oscillations or pulses is related to the degree to which the shaft is rotated. The modulated optical output is detected with a pair of light-sensitive diodes housed within the encoder. These diodes generate electrical analog signals in response to the modulated optical output.

Generally analog signals from an optical encoder such as the Cannon K1 are processed by an external interpolation circuit to measure position. Such circuitry makes a low-resolution measurement based on a counting of the number of sinusoidal pulses from the encoder. Sometimes a more precise position measurements may be obtained by dividing a single analog sinusoidal pulse from the encoder into many square pulses, such as 40, and counting each square pulse through an external computation device to determine the position of the external measurement device.

### SUMMARY OF THE INVENTION

The invention is based on the discovery that high-resolution position measurement can be achieved by processing phase displaced signals indicative of position, especially by selecting a preferred quadrature signal at each point for fine position calculation. The invention provides a position-measuring system, especially a position encoder signal analysis system that produces fine position measurement. The invention also provides methods for high-resolution position measurement. Such high-resolution position measurement has many useful applications. For example, in an infusion pump, the position measurement can be used to measure volume displacement, provide flow control and continuity at a low infusion rate, and control the quality of an infusion process.

The invention and its other advantages will be apparent from the following detailed description, and from the claims.

### BRIEF DESCRIPTION OF THE DRAWINGS

These and other objects and advantages of the invention will become more apparent and more readily appreciated from the following exemplary embodiment of the invention taken in combination with the accompanying drawings, of which:

FIG. 1 is a diagram illustrating the fluid delivery system.

FIG. 2 is a diagram illustrating the position measuring system.

FIG. 3 is a diagram illustrating the diffraction gratings of the optical unit of the position measuring system and the moire fringe pattern resulting from displacement of the crossed gratings in the optical unit.

FIG. 4 is an electrical block diagram of the electronic unit of the position measuring system.

FIGS. 5A and 5B are, respectively, digitized high-resolution quadrature quasi-sinusoidal waveforms and two digitized low-resolution square waveforms.

### DETAILED DESCRIPTION OF EXEMPLARY EMBODIMENT

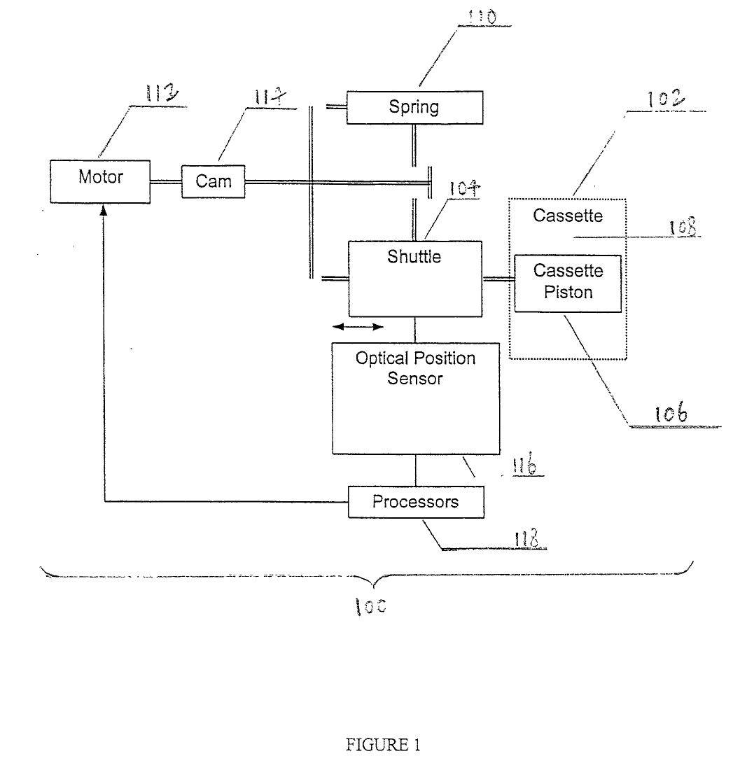

One of the applications of the position measuring system is to measure the position of a shuttle operably linked to a cassette piston in an infusion pump. FIG. 1 shows a block diagram of one embodiment of the present invention. The fluid delivery system 100 includes a cassette assembly 102 and a shuttle mechanism 104. A suitable cassette assembly is described in patent application Ser. No. 60/216,658, filed Jul. 7, 2000, entitled “Cassette”, to Carlisle, Costa, Holmes, Kirkman, Thompson and Semler, the entire contents of which are incorporated herein by reference. Within the cassette assembly 102 is a cassette piston 106 and a cassette central chamber 108. A spring 110 biased shuttle mechanism 104 is connected to the cassette piston 106. Piston 106 slides freely to draw fluid into the cassette central chamber 108 and pump fluid out of central chamber 108. A motor 112 is activated in one direction to draw the cassette piston 106 out of cassette central chamber 108 via cam 114 and shuttle 104. When the cassette piston 106 is fully withdrawn, shuttle 104 disengages from cam 114 and motor 112, so that spring 110 pushes the cassette piston 106 into the cassette central chamber 108 via shuttle 104 to apply positive pressure to the fluid in the cassette central chamber 108. The shuttle mechanism 104 is also operably linked to an optical position sensor 116. A processor 118 is connected to motor 112 and the position sensor 116.

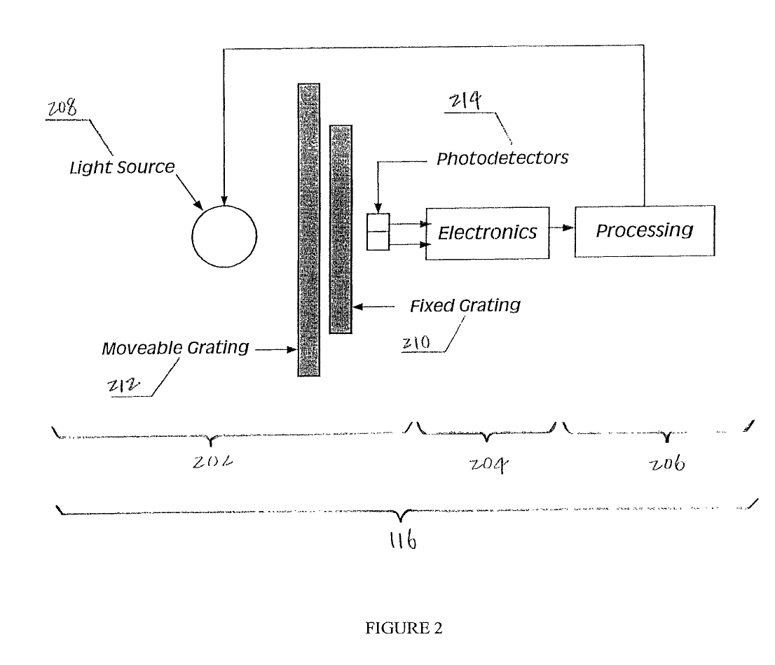

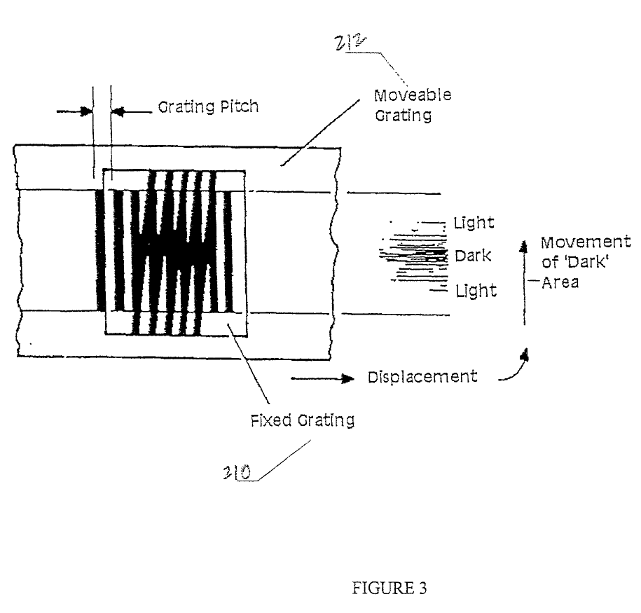

FIG. 2 shows a block diagram of optical position sensor 116. The position measuring system 116 contains an optical unit 202, an electronic unit 204, and a processing unit 206. In the optical unit 202 as shown in FIG. 2 and FIG. 3, an illumination source 208 illuminates two crossed gratings, with grating 210 being fixed and grating 212 being movable. The movable grating 212 is attached to a device the position of which is to be monitored such as a shuttle coupled to a cassette piston in an infusion pump. In one embodiment, the gratings are identical square wave transmission gratings positioned at a small angular displacement relative to each other, e.g., typically less than 10 degrees. Illumination is usually received by two closely spaced photodetectors 214. The two photodetectors 214 are positioned in quadrature, i.e., one photodetector is positioned so that there is a 90 degree phase shift in received light intensity with respect to light received by the other photodetector. As the movable grating 212 is displaced relative to the fixed grating 210, the resulting moire fringes move in a perpendicular direction (see FIG. 3) according to the relationship:

tan (α)=(grating displacement)/(fringe displacement),

where α is the angle between the two gratings. Because the two photodetectors 214 are positioned in quadrature, both the magnitude and the direction of the displacement can be sensed.

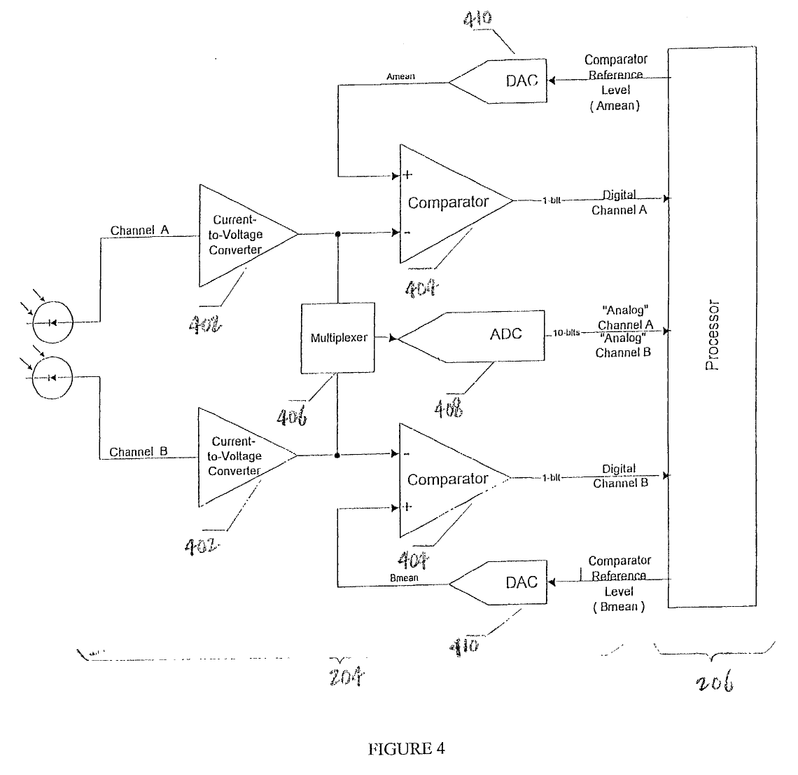

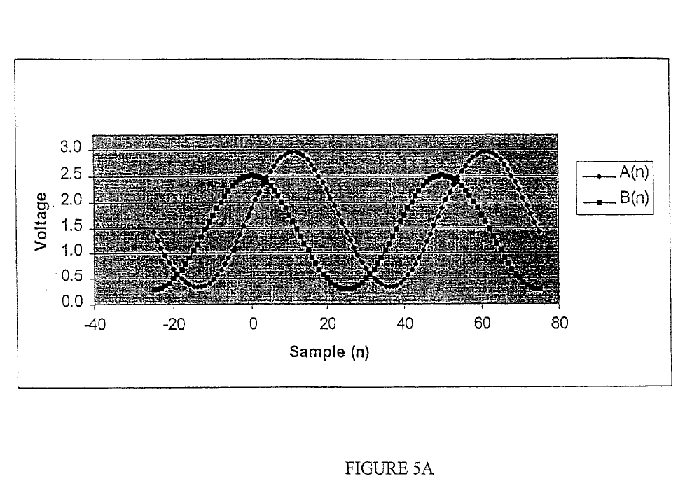

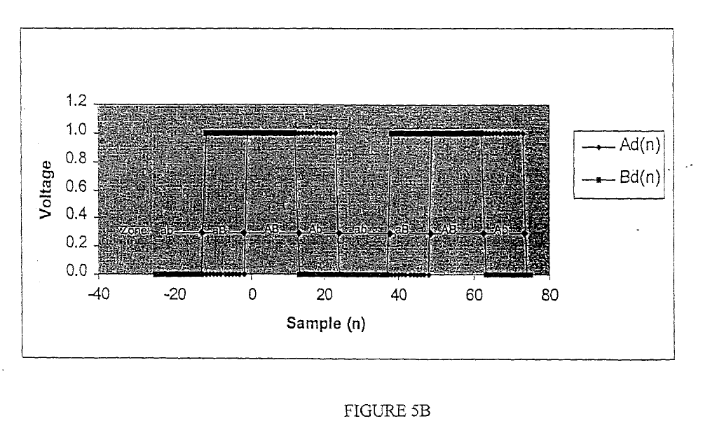

FIG. 4 shows a block diagram of the electronic unit illustrating the electronic processing of the signals generated by the optical unit 202. The photodetectors 214 generate analog current signals as A and B related to incident light intensity. Each analog current signal is fed through a current-to-voltage converter 402 to be transformed into a voltage signal, e.g., voltage signal A and B (see FIG. 5A), both of which are processed by a low- and high-resolution processing unit. The low-resolution processing unit includes comparators 404 for coarse analog to digital (AID) conversion of the input voltage signals (see FIG. 5B). The voltage signals of channel A and B are also received by the high-resolution processing unit including a multiplexer 406 which alternately outputs the analog voltage signals from channel A and channel B to an A/D converter (ADC) 408. The processing unit 206 contains a processor which determines the position of the movable grating 212 by processing the data output from the low-resolution and high-resolution processing units. The processing unit 206 also determines the comparator reference levels which are applied to comparators 404 through digital to analog (D/A) converters 410.

In operation, the position of the shuttle is responsive to the position of the cassette piston which correlates with the fluid volume displaced by the infusion pump. Thus the position measuring system can be used to measure the volume displaced by the infusion pump. The position information is processed by the optical unit 202, which is an optical encoder that translates position information to optical output signals and subsequently analog current signals. The analog current signals are converted to analog voltage signals by current to voltage converters 402 which are in turn processed by the low and high-resolution processing units. In the low-resolution processing unit, each comparator 404 compares the voltages of the analog input signal to a comparator reference level and generates a binary output voltage, e.g., 0 output voltage if the analog input signal voltage is less than the reference level and 1 output voltage if the analog input signal voltage is greater than the reference level. The comparator reference level for digital channel A is Aₘₑₐₙ and for digital channel B is Bₘₑₐₙ, where Aₘₑₐₙ and Bₘₑₐₙ are the mean values of the A and B channel waveforms, respectively and are applied to the comparators 404 through digital to analog (D/A) converters 410. The processor 206 updates the comparator reference levels from time to time to account for variations over time in Aₘₑₐₙ and Bₘₑₐₙ.

The output signals of the low-resolution processing unit form the digital square waveforms Ad and Bd as shown in FIG. 5B. A digital processor 206 counts the number of high and low levels or transitions between levels of the digital square waveforms of the comparators 404 and provides an integer number indicating position at a low-resolution. For example, the number of high/low levels or transitions represents units of grating quarter-periods. If each grating quarter-period is defined as a zone, then zone-count provides an estimate of position in units of grating quarter-periods, i.e., the resolution of position measurement is about one quarter the grating period. In one embodiment, each transition between levels of the digital square waveforms causes an interrupt in processor 206 which is time stamped by the processor clock. The time stamps can be used in further processing as described below.

The zone type for a given position is known from the squared pulses. For example, four zone types can be defined for positions of a shuttle coupled to a cassette piston traveling in the fill direction in an infusion pump. The four zone types are zone Ab, where A is high and B is low; zone AB, where A is high and B is high; zone aB, where A is low and B is high; and zone ab, where A is low and B is low (as shown in FIG. 5B). Similarly the direction of the shuttle motion, e.g., fill or empty can be determined by processor 206 from the sequence of interrupts on the digital channels A and B. In the fill direction the repeating sequence of interrupts is A-rising, B-rising, A-dropping, B-dropping. In the empty direction the repeating sequence of interrupts is A-rising, B-dropping, A-dropping, B-rising. For shuttle motion in one direction, e.g., fill direction, each transition causes the low resolution digital position count to be incremented. For shuttle motion in the opposite direction, e.g., empty direction, each transition, causes the digital position count to be decremented.

The phase relation between the two digital square waveforms can be determined by the processor 206 and used to control the quality of the position measuring system 116. In one embodiment, the phase relation of the two digital square waveforms Ad and Bd as shown in FIG. 5B is 90 degrees. In operation, processor 206 periodically measures the phase relation of the square waveforms Ad and Bd and compares such measurement with a pre-stored phase value: any major deviation between the measured phase value and the pre-stored phase value indicates abnormality of the position system and triggers a responding action of the system. In one embodiment, the processor 206 measures the phase relation of the digital square waveform via the time stamps of each interrupt caused by the square waveform. For example, if the transitions from zone ab to aB, aB to AB, AB to Ab, Ab to ab, and ab to aB as shown in FIG. 5B are time stamped or labeled as TS1, TS2, TS3, TS4, and TS5, respectively (where TS1<TS2<TS3<TS4<TS5), then the phase relation between the two digital waveforms Ad and Bd as shown in FIG. 5B is determined as the following:

[(TS2−TS1)+(TS4−TS3)]/(TS5−TS1)=% of 180 degrees.

To perform the phase relation measurement, the processor 206 measures the phase relation of the digital square waveforms Ad and Bd via first selecting a set of zones representing a constant moving speed and then measuring the phase relation based on the selected set of zones. In general, the speed of the shuttle 104 operably linked to cassette piston 106 changes, e.g., accelerates and decelerates as the cassette piston 106 slides to draw fluid into and pump fluid out of the cassette central chamber 108. Accordingly, the time difference between successive interrupts, e.g., the time difference between successive time stamps varies as the speed changes. When the position movement changes from acceleration to deceleration, the speed is considered to be constant. During a fill cycle when the fluid is drawn into the cassette central chamber 108 the processor 206 obtains and analyzes a full set of interrupts within the cycle, e.g., approximately eighty time stamps. Starting at interrupt TS5, the processor 206 looks backward and forward for four time stamps. It then calculates the delta T backward, e.g., dTb=TS5−TS1, the delta T forward, e.g., dTf=TS9−TS5, and DT=|dTf−dTb|. A similar calculation is repeated for time stamps TS6 through the fourth from the last. The processor 206 saves the index of the central time stamp that produces the minimum DT value, representing an approximate constant speed profile of the interrupts and uses this central time stamp and its adjacent time stamps for phase measurement.

In the high-resolution processing unit, the ADC 408 generates high-resolution digitized “analog” signals by converting the analog signals of channels A and B into digital values, e.g., ADC counts. Such high-resolution digitized “analog” signals represent quasi-sinusoidal waveforms, i.e., digital representation of analog signals of channels A and B as shown in FIG. 5A. The micro controller of the processing unit 206 reads the digitized values corresponding to channels A and B and selects the sample value A or B whichever corresponds to or represents a more rapidly changing waveform at the position, e.g., whichever is closer to its respective channel mean relative to each channel's amplitude, i.e.,Aₘₐₓ−Aₘᵢₙ or Bₘₐₓ−Bₘᵢₙ. The digitized values for the selected channel are used to determine the slope for the selected waveform. The digitized values of the selected channel, including the corresponding slope value are used for position measurement.

Normally before the measurement starts, waveform parameters are determined and stored in the memory of the processing unit 206. For example, to measure the shuttle position in an infusion pump, before the pump is put into service the processor 206 adjusts the current to the light source 208 so that the maximum and minimum values of channel A and channel B waveforms, e.g., Aₘᵢₙ, Aₘₐₓ, Bₘᵢₙ, and Bₘₐₓ are within a prescribed percentage of the full ADC scale, typically within about 10% over the full excursion of the shuttle, without clipping. Thus the input to the ADC essentially covers the full dynamic range of the ADC, yielding optimal resolution in the output samples. The values Aₘᵢₙ, Aₘₐₓ, Bₘᵢₙ, and Bₘₐₓ are stored in the micro controller memory of the processing unit 206. Then the mean value and the slope at the mean value for channel A and channel B waveforms are calculated as follows:

Aₘₑₐₙ=(Aₘᵢₙ+Aₘₐₓ)/2

Aₛₗₒₚₑ=C1 (Aₘₐₓ−Aₘᵢₙ),

Bₘₑₐₙ=(Bₘᵢₙ+Bₘₐₓ)/2

Bₛₗₒₚₑ=C2 (Bₘₐₓ−Bₘᵢₙ)

C1 and C2 are scale parameters empirically determined offline. The values of C1 and C2 are used to create a lookup table stored in the micro controller memory. The lookup table provides a slope value at the mean of the respective waveform, e.g., Aₛₗₒₚₑ or B_{sclope}. For example, the lookup table accepts as input a range value, e.g., (Aₘₐₓ−Aₘᵢₙ) or (Bₘₐₓ−Bₘᵢₙ) and provides a corresponding slope value, e.g., Aₛₗₒₚₑ or Bₛₗₒₚₑ as output. The values of Aₘₑₐₙ, Aₛₗₒₚₑ, Bₘₑₐₙ, and Bₛₗₒₚₑ are also stored in the micro controller memory. The Aₘₑₐₙ and Bₘₑₐₙ are also used to reset the reference levels of the comparators 404 through D/A converters 410.

All stored waveform parameters are periodically updated during position measurement to ensure the quality of the position system. For example, the waveform parameters of an infusion pump are updated during even numbered fill cycles, alternating between channel A and B, e.g., updating stored channel A waveform parameters during every 4^{th} fill cycle, starting with the 2^{nd} while updating stored channel B waveform parameters during every 4^{th} fill cycle, starting with the 4^{th}.

The position measurement is determined by the position count or zone-count and a fractional position. The fractional position is a percentage of a zone and is calculated using point-slope linear interpolation. At a given point or time, sample value A or B whichever corresponds to or represents a more rapidly changing waveform at the position or whichever is closer to its respective channel mean relative to each channel's amplitude, e.g. Aₘₐₓ−Aₘᵢₙ or Bₘₐₓ−Bₘᵢₙ, is selected as the sample value. For example, if |(A−Aₘₑₐₙ)/(Aₘₐₓ−Aₘᵢₙ)|<|(B−Bₘₑₐₙ)/(Bₘₐₓ−Bₘᵢₙ)|, then sample A is chosen, otherwise sample B is chosen. Near its mean, a linear segment may approximate the waveform. Thus choosing the sample that is closest, as a percentage of its amplitude, to its corresponding waveform mean minimizes the error in subsequent linear interpolation.

For a given shuttle position point, the point-slope linear interpolation is based on the zone type, the selected sample value, the selected waveform mean, and the slope value at the waveform mean.

The fractional position and the final position measurement, e.g., the shuttle position are calculated per the following table.

| Zone | Sample | | |
|---|---|---|---|
| Type | Value | Fractional Position | Final Position |
| Ab | A | (A-Aₘₑₐₙ)*Aₛₗₒₚₑ | ZoneCount + Fraction |
| Ab | B | (B-Bₘₑₐₙ)*Bₛₗₒₚₑ | ZoneCount + 1 + Fraction |
| AB | A | (A-Aₘₑₐₙ)*( −Aₛₗₒₚₑ) | Zone Count + 1 + Fraction |
| AB | B | (B-Bₘₑₐₙ)*Bₛₗₒₚₑ | Zone Count + Fraction |
| AB | A | (A-Aₘₑₐₙ)*( −Aₛₗₒₚₑ) | Zone Count + Fraction |
| AB | B | (B-Bₘₑₐₙ)*( −Bₛₗₒₚₑ) | Zone Count + 1 + Fraction |
| Ab | A | (A-Aₘₑₐₙ)*Aₛₗₒₚₑ | Zone Count + 1 + Fraction |
| Ab | B | (B-Bₘₑₐₙ)*( −Bₛₗₒₚₑ) | Zone Count + Fraction |

In one embodiment of the present invention, the position measuring system includes an external reference signal which can be used to confirm or reset the position of the system. For example, in an infusion pump the processor reads an external reference signal from a switch which is triggered by a particular position of the shuttle 104, e.g., End of Shuttle (EOS), and resets the shuttle position accordingly.

In an alternative embodiment, the ADC output samples are time stamped and used directly (without calculating fractional position) to determine the state of movement of the pump shuttle; that is, to determine if the shuttle has moved or not moved, but not how far it has moved. This technique is especially helpful at very low flow rates, where additional resolution (beyond that provided by the interrupts alone) is required to achieve the desired flow continuity. If the shuttle is not moving, then the ADC output valve (voltage) will not change (noise excepted). When the shuttle moves a small amount, less than one zone, then the ADC output will change a small amount.

Usually when an infusion rate is set to be very low, the infusion pump operates in a pulse mode in which an outlet valve in the cassette is periodically opened for brief instants. Typically, 80 digital values or ADC counts may occur between two successive interrupts caused by the square waveform. To obtain desired flow continuity at a low flow rate, the pump flow control algorithm can set a desired target value of ADC counts, e.g., 10, 20, or 40 for each pulsing or brief opening of the outlet valve. According to one embodiment of the present invention, processor 206 monitors the ADC counts before and after each opening of the outlet valve by selecting via processor 206 either sample value A or B whichever represents the most movement, e.g., has the most number of ADC counts. The processor 206 compares the selected value with the target value and adjusts the pulsing of the outlet valve so that the ADC count for the next pulsing approaches the desired target value.

In another embodiment, the high-resolution digitized “analog” signals of the position measuring system is used to monitor the fine shuttle movement, thus monitor the stability of the cassette in an infusion pump. For example, after each empty or fill movement the processor 206 checks the ADC output signals to determine whether the shuttle position sufficiently stands still. Usually the processor 206 takes several, e.g., about 8, ADC readings and analyzes them for trending. A trend above the background noise level indicates movement of shuttle position in response to leakage of the cassette and triggers an alarm device.

### Other Embodiments

Although several exemplary embodiments of this invention have been described in detail above, those skilled in the art will readily appreciate that many modifications are possible in the exemplary embodiment without materially departing from the novel teachings and advantages of this invention. Accordingly, all such modifications are intended to be included within the scope of this invention as defined in the following claims.

What is claimed is:

1. A method of measuring a position comprising:
receiving at least two phase displaced signals in response to the position;
selecting one of the phase displaced signals for measuring the position; and
determining the position based on the selected signal.

2. The method of claim 1, wherein the two phase displaced signals are analog signals.

3. The method of claim 1, wherein the two phase displaced signals are quadrature.

4. The method of claim 1, wherein the two phase displaced signals are digital representations of two phase displaced analog signals.

5. The method of claim 1, wherein the two phase displaced signals are two sinusoidal or quasi-sinusoidal waveforms.

6. The method of claim 5, wherein the two waveforms are digital representations of two analog waveforms.

7. The method of claim 1, wherein the two phase displaced signals are generated by an optical encoder comprising two gratings.

8. The method of claim 1, wherein of the two phase displaced signals the selected signal has a more rapidly changing waveform at the position.

9. The method of claim 1, wherein the position determination includes point-slope straight-line interpolation based on the selected signal.

10. The method of claim 1, wherein the position being measured is related to a position of a pumping element in an infusion pump.

11. A method of measuring a position comprising:
transforming a position into two phase displaced output signals;
processing the two phase displaced output signals to generate two digital square waveforms;
identifying a selected one of the output signals for the position based on the output signals; and
determining the position according to the two digital square waveforms and the selected output signal.

12. The method of claim 11, wherein the transformation further comprises transforming a position into an optical signal generated by two gratings and transforming the optical signal into two phase displaced output signals.

13. The method of claim 11, wherein the position determination includes determining zone-count and determining fractional position, wherein the zone-count is determined based on the digital square waveforms and the fractional position is determined based on the selected output signal.

14. The method of claim 11, wherein the identification of the selected output signal includes selecting one of the two output signals having a value for the position that is closer to its corresponding output signal mean relative to its corresponding output signal amplitude.

15. The method of claim 11, wherein the identification of the selected output signal includes selecting one of the two output signals that has a more rapidly changing waveform at the position.

16. A method of measuring volume displaced by an infusion pump comprising:
transforming a position into two phase displaced output signals, wherein the position is in response to volume displacement of the infusion pump;
processing the two phase displaced output signals to generate two digital square waveforms;
identifying a selected one of the output signals for the position based on the output signals;
determining the position according to the two digital square waveforms and the selected output signal; and
determining the volume displaced by the infusion pump according to the position.

17. The method of claim 16, wherein the transformation further comprises transforming the position into an optical signal generated by two gratings and transforming the optical signal into two phase displaced output signals.

18. A method of detecting a position movement of an object comprising:
transforming a signal of a position movement into a high-resolution digitized analog signal; and
detecting the digitized analog signal, wherein the detection of the digitized analog signal indicates the position movement.

19. The method of claim 18, wherein the transformation is performed by an analog to digital converter.

20. The method of claim 18, wherein the detection further comprises detecting the digitized analog signal a plurality of times.

21. The method of claim 18, wherein the position movement is in response to a cassette leakage in an infusion pump.

22. A method of monitoring a volume displacement in a pump comprising:
transforming a position of a pumping element in the pump into two phase displaced output signals, wherein the position is in response to a volume displacement of the pumping element;
processing the two phase displaced output signals to generate two high-resolution digitized analog signals;
identifying a selected one of the digitized analog signals for the position based on the digitized analog signals; and
monitoring the volume displacement based on the selected digitized analog signal.

23. The method of claim 22, wherein the identifying includes selecting the output signal having the greater value change for a volume displacement.

24. The method of claim 22, wherein the monitoring includes comparing the value change of the selected digitized analog signal to a pre-determined value.

25. A method for monitoring the quality of a position measuring system comprising:
calculating phase relation of two phase displaced output signals of a position measuring system; and
comparing the phase relation to a pre-determined value, wherein a deviation of the phase relation from the pre-determined value indicates abnormality of the position system.

26. The method of claim 25, wherein the calculation of the phase relation further comprises processing the two phase displaced output signals to generate two digital square waveforms and time labeling each transition of the square waveforms.

27. The method of claim 26, wherein calculation of the phase relation is based on a selected set of time labels of the transitions.

28. The method of claim 27, wherein the selected set of time labels represents a time period when position moving speed is constant.

29. A system for measuring a position comprising:
a processing unit responsive to two sinusoidal or quasi-sinusoidal waveforms and two digital square waveforms for measuring the position, wherein the processing unit:
selects one of said two waveforms for the position;
calculates a first value from the two digital square waveforms;
calculates a second value from the selected sinusoidal waveform for the position; and
adds the first and second values to measure the position.

30. A system for measuring a position comprising:
an optical unit generating two phase displaced analog signals in response to a position;
a low-resolution processing unit connected to the optical unit which generates two digital square waveforms from the two phase displaced analog signals;
a high-resolution processing unit connected to the optical unit which generates two digitized waveforms corresponding to the two phase displaced analog signals; and
a processing unit, responsive to the two digital square waveforms from the low-resolution processing unit and the two digitized waveforms from the high-resolution processing unit, wherein the processing unit comprises a processor which:
selects a digitized waveform for the position;
calculates a first value from the two digital square waveforms;
calculates a second value from the selected digitized waveform for the position; and
adds the first and second values to measure the position.

31. The system of claim 30, wherein the optical unit comprises two photodetectors positioned in quadrature.

32. The system of claim 30, wherein the optical unit is connected to a pumping element of an infusion pump.

33. The system of claim 30, wherein the position is in response to a position of a pumping element in an infusion pump.

34. The system of claim 30, wherein the processor further provides a value of volume displacement in response to the position.

35. The system of claim 30, wherein the low-resolution processing unit generates the two digital square waveforms based on at least one reference value provided and updated by the processing unit.

36. The system of claim 35, wherein there are two reference values.

37. The system of claim 35 wherein the processing unit updates the reference value based on digitized waveform mean.

38. The system of claim 30, wherein the processing unit controls the amplitude of the two phase displaced analog signals generated by the optical unit.

39. The system of claim 38, wherein the processing unit controls the amplitude by controlling the intensity of a light source in the optical unit.

40. The system of claim 30, wherein the processing unit resets the position in response to an external signal.

41. A system for processing output signals from an encoder comprising:
a low-resolution unit receiving two phase displaced analog signals from an encoder and generating two digital square waveforms from the two phase displaced analog signals;
a high-resolution processing unit receiving the two phase displaced analog signals and generating two digitized waveforms from the two phase displaced analog signals; and
a processing unit, responsive to the two digital square waveforms from the low-resolution processing unit and the two digitized waveforms from the high-resolution processing unit, wherein the processing unit comprises a processor including:
selecting means for selecting a selected digitized waveform for the position;
first calculating means for calculating a first value from the two digital square waveforms;
second calculating means for calculating a second value from the selected digitized waveform for the position;
adding means for adding the first and second values to measure the position.

42. A system for measuring a position comprising:
a processing unit responsive to two phase displaced waveforms in response to a position, wherein the processing unit selects one of said two phase displaced waveforms for measuring the position and determining position based on the selected waveform.

43. The system of claim 42, wherein the processing unit selects one of said two phase displaced waveforms having a value for the position that is closer to its corresponding waveform mean relative to its corresponding waveform amplitude.

44. The system of claim 42, wherein the processing unit selects one of said two phase displaced waveforms having a more rapidly changing waveform at the position.

45. The system of claim 42, wherein the two phase displaced waveforms are two sinusoidal or quasi-sinusoidal waveforms.

46. The system of claim 42, wherein the two phase displaced wavefont is are analog signals.

47. The system of claim 42, wherein the two phase displaced waveforms are digital representations of two analog signals.

48. A system for monitoring a volume displacement in a pump comprising:
a high-resolution processing unit transforming a position of a pumping element in the pump into two phase displaced digitized analog signals, wherein the position is in response to a volume displacement; and
a processing unit responsive to the two phase displaced digitized analog signals from the high-resolution processing unit, wherein the processing unit selects one of the two digitized analog signals for the position, and monitors the volume displacement based on the selected digitized analog signal for the position.

49. The system of claim 48, wherein the processor selects one of the two digitized analog signals having the greater value change for the volume displacement.

50. The system of claim 48, wherein the processor monitors the volume displacement by comparing the value change of the selected digitized analog signal to a pre-determined value.

51. A system for measuring volume displaced by an infusion pump comprising:
a low resolution processing unit generating two digital square waveforms from two phase displaced analog signals in response to a position of a pumping element corresponding to a volume displaced by an infusion pump,
a high-resolution processing unit generating two digitized analog waveforms corresponding to the two phase displaced analog signals; and
a processing unit, responsive to the two digital square waveforms from the low-resolution processing unit and the two digitized analog waveforms from the high-resolution processing unit, wherein the processing unit comprises a processor which
selects a digitized waveform for the position;
calculates a first value from the two digital square waveforms;
calculates a second value from the selected digitized analog waveform for the position;
adds the first and second values to measure the position; and
measures the volume displaced by the infusion pump based on the position.
The system of claim 51, wherein the two phase displaced analog signals are generated by an optical unit.

52. A system for monitoring the quality of a position measuring system comprising:
a processing unit responsive to two phase displaced output signals of a position measuring system, wherein the processing unit comprises a processor which
calculates the phase relation of the two phase displaced output signals of the position measuring system, and
compares the phase relation to a pre-determined value, wherein a deviation of the phase relation from the pre-determined value indicates abnormality of the position system.
